(19) United States
(12) Patent Application Publication
(10) Pub. No.: US 2026/0324341 A1
(43) Pub. Date: Oct. 15, 2026

(54) SEPARATING APPARATUS AND SEPARATING METHOD

(71) Applicant: DISCO CORPORATION, Tokyo (JP)

(72) Inventors: Ryota AOKI, Tokyo (JP); Kunimitsu TAKAHASHI, Tokyo (JP)

(21) Appl. No.: 19/637,338

(22) Filed: Apr. 2, 2026

(30) Foreign Application Priority Data
Apr. 9, 2025 (JP) 2025-064064

(51) Int. Cl. H10P 72/00; H10P 72/70

(52) U.S. Cl. CPC H10P 72/0428; H10P 72/744

(57) ABSTRACT

A separating apparatus for separating a first substrate from a bonded substrate where a first wafer and a second substrate are bonded with a bonding member, where the first wafer includes the first substrate and devices formed on a surface of the first substrate, to transfer the devices to the second substrate is provided. The separating apparatus includes a water supply unit to supply water or water vapor to an outer peripheral edge of the bonded substrate, a volume expansive unit to emit a laser beam having a wavelength absorptive in the water onto the water directly or through the first substrate or the second substrate for causing the water to expand in a volume thereof, and a separating mechanism to hold at least one of the first substrate or the second substrate and separate the first substrate and the second substrate from each other.

### CROSS REFERENCE TO RELATED APPLICATION

This application is based upon and claims the benefit of priority from the prior Japanese Patent Application No. 2024-064064 filed on April 9, 2025; the entire contents of which are incorporated herein by reference.

### FIELD

The present disclosure relates to a separating apparatus and a separating method.

### BACKGROUND

In accordance with recent trends toward higher performance and higher integration of device chips, a technology to transfer devices, which are formed on a surface of one of two bonded wafers, to the other or the bonded wafers has been developed. For separating the two wafers bonded with a bonding film, as disclosed in, for example, Japanese Patent Application Laid-Open Publication No. 2015-217421 and Japanese Patent Application Laid-Open Publication No. 2016-021464, a laser beam may be focused within the bonding film or on an interface between one of the two wafers and the bonding film, and an irradiation position with the laser beam may be moved relatively in a planar direction. As such, a separation starting point may be formed planarly in the bonded wafer, and the two wafers may be separated from each other reliably by an impact applied to an edge of the planar separation-starting point.

### SUMMARY

However, the separating apparatuses and the separating methods described in the above publications exhibit a problem such that the impact applied to the edge of the wafer may cause chipping. Accordingly, a separating apparatus and a separating method by which damages on an outer peripheral edge of a wafer may be prevented are demanded.

The present disclosure has been made in view of the above, and an object thereof is to provide a separating apparatus and a separating method, by which chipping or cracking of an outer periphery of a wafer may be prevented.

According to an aspect of the present disclosure, a separating apparatus is configured to separate a first substrate from a bonded substrate where a first wafer and a second substrate are bonded with a bonding member, where the first wafer includes the first substrate and devices formed on a surface of the first substrate, to transfer the devices to the second substrate. The separating apparatus includes a water supply unit configured to supply water or water vapor to an outer peripheral edge of the bonded substrate, a volume expansive unit configured to emit a laser beam having a wavelength absorptive in the water onto the water supplied by the water supply unit directly or through the first substrate or the second substrate for causing the water to expand in a volume thereof, and a separating mechanism configured to hold at least one of the first substrate or the second substrate and separate the first substrate and the second substrate from each other.

According to another aspect of the present disclosure, a separating method for separating a first substrate from a bonded substrate where a first wafer and a second substrate are bonded with a bonding member, where the first wafer includes the first substrate and devices formed on a surface of the first substrate, and transferring the devices to the second substrate, is provided. The method includes forming a separation starting point at least on an outer peripheral edge of the first wafer at a boundary between the devices and the first substrate by supplying water or water vapor to the outer peripheral edge of the first wafer and emitting a laser beam having a wavelength absorptive in the water onto the water and causing the water to expand in a volume thereof, and holding at least one of the first substrate or the second substrate and separating the first substrate and the second substrate from each other.

According to the present disclosure, occurrence of chipping or cracking of the outer periphery of the wafer may be prevented.

### BRIEF DESCRIPTION OF THE DRAWINGS

FIG. 1 is a perspective view illustrating an example of a separating apparatus according to the present embodiment.

FIG. 2 is a diagram illustrating an example of a separation starting point forming step (forming a separation starting point) according to the present embodiment.

FIG. 3 is a diagram illustrating the example of the separation starting point forming step (forming a separation starting point) according to the present embodiment.

FIG. 4 is a diagram illustrating the example of the separation starting point forming step (forming a separation starting point) according to the present embodiment.

FIG. 5 is a diagram illustrating an example of a separating step (separating) according to the present embodiment.

FIG. 6 is a diagram illustrating the example of the separating step (separating) according to the present embodiment.

### DESCRIPTION OF EMBODIMENTS

An embodiment of the present disclosure will be described below with reference to the accompanying drawings.

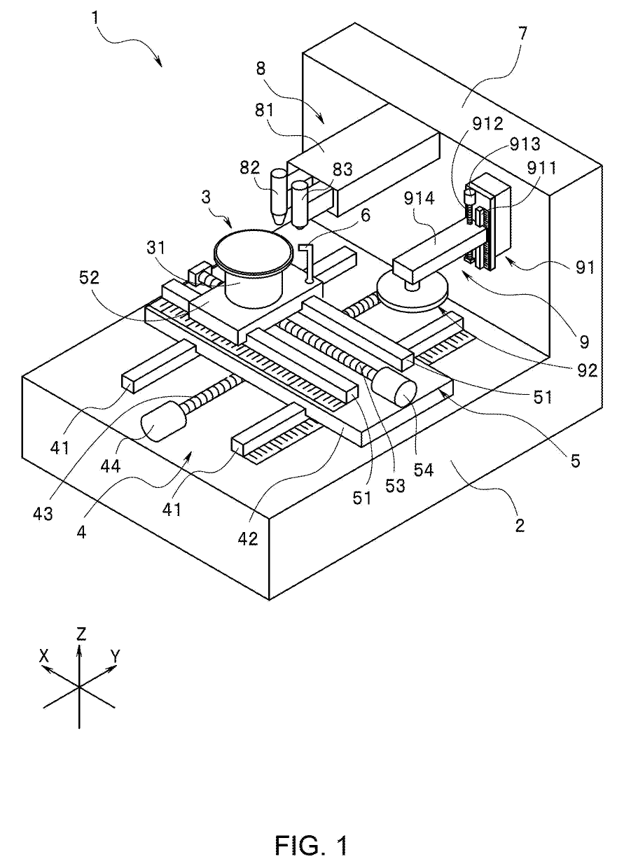

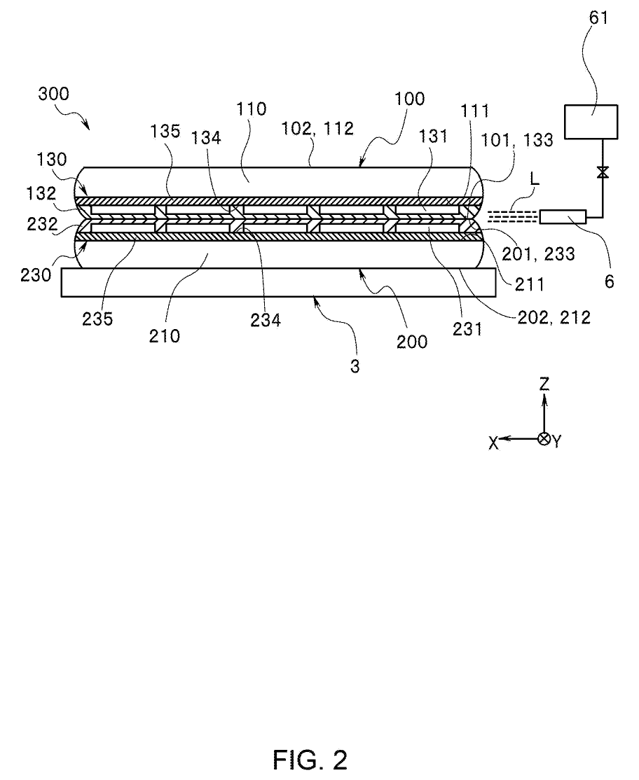

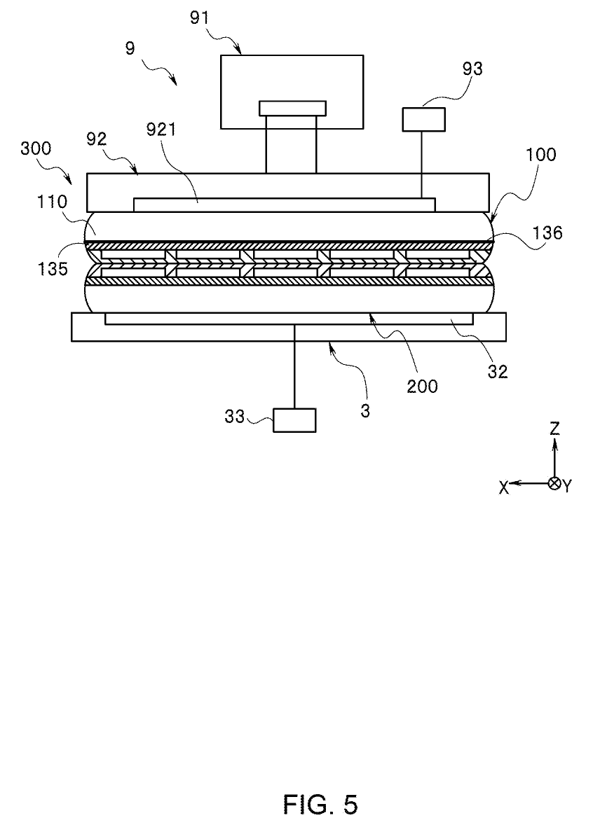

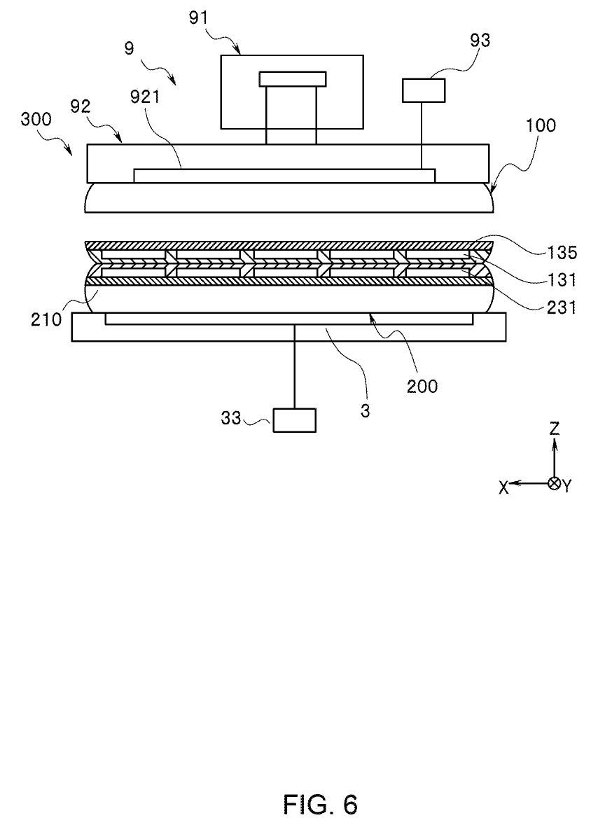

In the present disclosure, a term such as "xx step" may be interpreted (equated) as "xx-ing." For example, a term "separation starting point forming step" may be read as "forming a separation starting point, " and a term "separating step" may be read as "separating." FIG. 1 is a perspective view illustrating an example of a separating apparatus according to the present embodiment. FIGS. 2-4 are diagrams illustrating an example of a separation starting point forming step according to the present embodiment. FIGS. 5-6 are diagrams illustrating an example of a separating step according to the present embodiment. In the following description, a left-right direction in FIG. 1 will be referred to as an "X-axis direction," a front-rear direction is referred to as a "Y-axis direction," and a vertical direction is referred to as a "Z-axis direction."

A separating apparatus 1 shown in FIG. 1 is an apparatus configured to separate a first substrate 110 (see FIG. 2) from a bonded substrate 300 (see FIG. 2) held on a chuck table 3. The separating apparatus 1 includes a Y-axis moving unit 4 and an X-axis moving unit 5 on a base 2. The Y-axis moving unit 4 is configured to move the chuck table 3 in the Y-axis direction. The Y-axis moving unit 4 includes a pair of guide rails 41 extending in the Y-axis direction, a movable plate 42 supported movably in the Y-axis direction on the guide rails 41, a ball screw 43 arranged in parallel with the guide rails 41, and a motor 44 to rotationally drive the ball screw 43. The ball screw 43 is screwed into a threaded portion (not shown) in the movable plate 42, and when the motor 44 rotates the ball screw 43, the movable plate 42 moves in the Y-axis direction along the guide rails 41. When the rotation direction of the ball screw 43 is reversed, a moving direction of the movable plate 42 in the Y-axis direction is switched. The X-axis moving unit 5 and the chuck table 3 are mounted on the movable plate 42 and may move in the Y-axis direction as the movable plate 42 moves.

The X-axis moving unit 5 may move the chuck table 3 in the X-axis direction. The X-axis moving unit 5 includes a pair of guide rails 51 extending in the X-axis direction, a movable plate 52 supported movably in the X-axis direction on the guide rails 51, a ball screw 53 arranged in parallel with the guide rails 51, and a motor 54 to rotationally drive the ball screw 53. The ball screw 53 is screwed into a threaded portion (not shown) in the movable plate 52, and when the motor 54 rotates the ball screw 53, the movable plate 52 moves in the X-axis direction along the guide rails 51. When the rotation direction of the ball screw 53 is reversed, a moving direction of the movable plate 52 in the X-axis direction is switched. A water supply unit 6 and the chuck table 3 are mounted on the movable plate 52 and may move in the X-axis direction as the movable plate 52 moves.

The chuck table 3 is mounted on the movable plate 52 via a table rotation mechanism 31. As shown in FIG. 5, a disc-shaped porous member 32 made of, for example, porous ceramic is incorporated into a central portion of an upper end of the chuck table 3. The porous member 32 is in communication with a suction source 33 such as a vacuum pump. When the bonded substrate 300 is placed on an upper surface of the chuck table 3 and the porous member 32 is evacuated by the suction source 33, a negative pressure is generated in the porous member 32, and a lower surface of the bonded substrate 300 is held by suction against the upper surface of the porous member 32 by being drawn by the negative pressure. The chuck table 3 is rotatable around an axis extending in the Z-axis direction while holding the bonded substrate 300 by suction.

The water supply unit 6 is connected to a water source 61 (see FIG. 2) and may jet water (or water vapor) L from a tip thereof. A tip portion of the water supply unit 6 is located above the upper surface of the chuck table 3 and extends toward a center of the chuck table 3 in a direction orthogonal to the Z-axis direction. In other words, the water supply unit 6 is configured to supply the water (or water vapor) L inward from a side to an outer peripheral edge of the bonded substrate 300 held on the upper surface of the chuck table 3. In the following description, the water or water vapor supplied from the water supply unit 6 is collectively referred to as water L.

On a rearward side (a +Y-axis direction side) of the base 2, a column 7 is provided upright. On a front surface (on a -Y-axis direction side) of the column 7, a volume expansive unit 8 and a separating mechanism 9 are arranged. The volume expansive unit 8 is a unit for emitting a laser onto the water L supplied from the water supply unit 6 and thereby causing the bonded substrate 300 to expand in its volume to form a separation starting point in the bonded substrate 300. The volume expansive unit 8 includes a casing 81 which is, for example, in a rectangular parallelepiped shape and extends horizontally in the Y-axis direction. An emitter head 82 is disposed at a tip portion of the casing 81, and the chuck table 3 is arranged to move in a path straight below the emitter head 82.

In the casing 81, a laser oscillator (not shown) such as a CO2 laser is disposed. A laser beam LB emitted horizontally in a -Y direction from the laser oscillator is reflected in a -Z direction by a mirror (not shown) to enter a condensing lens inside the emitter head 82, and is condensed and irradiates the bonded substrate 300 held on the chuck table 3. A height position of a focal point of the laser beam LB is adjustable in the Z-axis direction by a focal point position adjustment system (not shown). At the tip portion of the casing 81, an alignment unit 83 including, for example, a camera for detecting an irradiation position of the laser beam LB, is disposed alongside the emitter head 82.

The separating mechanism 9 is disposed on a rightward side (on a -X-axis direction side) of the volume expansive unit 8. The separating mechanism 9 is a unit for separating the first substrate 110 from the bonded substrate 300. The separating mechanism 9 includes a removing mechanism 91.

The removing mechanism 91 includes a guide 911 and a ball screw 912 that extend in the Z-axis direction, a motor 913 to rotationally drive the ball screw 912, and a movable plate 914 supported to movably in the Z-axis direction via the guide 911. The ball screw 912 is screwed into a threaded portion (not shown) in the movable plate 914, and when the motor 913 is driven to rotate the ball screw 912, the movable plate 914 moves in the Z-axis direction. When the rotation direction of the ball screw 912 is reversed, the moving direction of the movable plate 914 in the Z-axis direction is switched. The movable plate 914 is formed to extend horizontally in the Y-axis direction. On a lower surface of a tip portion of the movable plate 914, a holding pad 92 for holding an upper surface of the bonded substrate 300 by suction is disposed. The chuck table 3 is arranged to move in a path straight below the holding pad 92.

Next, the bonded substrate 300 to be separated will be described with reference to FIG. 2. FIG. 2 shows the bonded substrate 300 held on the chuck table 3.

The bonded substrate 300 is formed by bonding a disc-shaped first wafer 100 and a disc-shaped second wafer 200. The first wafer 100 has a front surface 101 and a back surface 102, which are surfaces orthogonal to a thickness direction, and is arranged such that the front surface 101 faces downward and the back surface 102 faces upward. The second wafer 200 has a front surface 201 and a back surface 202, which are surfaces orthogonal to the thickness direction, and is arranged such that the front surface 201 faces upward and the back surface 202 faces downward.

The first wafer 100 includes a first substrate 110 made of silicon, and a first device layer 130 formed on a front surface 111 side, which is a surface on one side in the thickness direction of the first substrate 110. The back surface 102 of the first wafer 100 is formed of a back surface 112 of the first substrate 110.

The first device layer 130 includes a plurality of first devices 131, a first surface film 132 formed as a bonding member on surfaces of the plurality of first devices 131, and an insulating film 135. The front surface 101 of the first wafer 100 is formed of a front surface 133 of the first surface film 132 in the first device layer 130. The first device layer 130 includes the first surface film 132, the first devices 131, and the insulating film 135 arranged in this order from the front surface in the thickness direction. In other words, the first wafer 100 is composed of the first surface film 132, the first devices 131, the insulating film 135, and the first substrate 110 in this order from the front surface 101 in the thickness direction.

Each of the plurality of first devices 131 includes an element that composes, for example, an IC, a semiconductor memory, or an image sensor. The plurality of first devices 131 are formed respectively in a plurality of regions partitioned by a plurality of streets 134 formed in a grid pattern.

The first surface film 132 may be any of a silicon oxide film (SiO2 film), a silicon carbide film (SiC film), a silicon nitride film (SiN film), a silicon carbonitride film (SiCN film), a SiOC film, a SiON film, and a TEOS film.

The insulating film 135 is laminated between the first substrate 110 and the first devices 131, and between the first substrate 110 and the first surface film 132 in portions where no first devices 131 are present, and is formed into a film for forming the first devices 131 on the front surface 111 side of the first substrate 110. Therefore, the first devices 131 are formed on a front surface (lower surface) of the insulating film 135. The insulating film 135 may be any of a silicon oxide film (SiO2 film), a silicon carbide film (SiC film), a silicon nitride film (SiN film), a silicon carbonitride film (SiCN film), a SiOC film, a SiON film, and a TEOS film.

Similarly to the first substrate 110 described above, the second wafer 200 includes a second substrate 210 made of silicon, and a second device layer 230 formed on a front surface 211, which is a surface on one side in the thickness direction of the second substrate 210. A back surface 202 of the second wafer 200 is formed of a back surface 212 of the second substrate 210.

The second device layer 230 is formed in an arrangement similar to the first device layer 130, and includes a plurality of second devices 231 and a second surface film 232 formed as a bonding member on surfaces of the plurality of second devices 231. A front surface 201 of the second wafer 200 is formed of a front surface 233 of the second surface film 232 in the second device layer 230. In the second wafer 200, similarly to the first wafer 100, an insulating film 235 is formed on the front surface 211 of the second substrate 210, and the second devices 231 are formed on a front surface (upper surface) of the insulating film 235.

Each of the plurality of second devices 231 includes an element similar to the first device 131. The second devices 231 are respectively formed in a plurality of regions partitioned by a plurality of streets 234 formed in a grid pattern, so as to be arranged in positions corresponding to the first devices 131. The second surface film 232 is made of a material bondable to the first surface film 132.

Prior to bonding the first and second wafers 100, 200, for example, the front surface 133 of the first surface film 132 of the first wafer 100 and the front surface 233 of the second surface film 232 of the second wafer 200 are each irradiated with plasma of a rare gas, which is generated using the rare gas and radio-frequency power. Thereby, the front surfaces 133, 233 of the first surface film 132 and the second surface film 232 are activated, and thereafter, the first and second wafers 100, 200 are bonded by plasma activation bonding effect of the front surfaces 133, 233. By this bonding, the bonded substrate 300 is formed, and the first devices 131 and the second devices 231 are bonded within the bonded substrate 300.

Optionally, the second wafer 200 may be composed solely of the second substrate 210 without having the second device layer 230. In other words, the bonded substrate 300 may have a structure where the first wafer 100, having the first devices 131 formed on the surface of the first substrate 110, and the second substrate 210 are bonded with the first surface film 132 which is the bonding member. Moreover, optionally, the second wafer 200 may be configured to have solely the second surface film 232 on the front surface 211 of the second substrate 210. In other words, the bonded substrate 300 may have a structure where the first wafer 100, having the first devices 131 formed on the surface of the first substrate 110, and the second substrate 210 are bonded with the first surface film 132 and the second surface film 232 which are bonding members.

Next, a separating method according to the present embodiment will be described. By performing the separating method in the present embodiment, the first substrate 110 may be separated from the bonded substrate 300, and the first devices 131 formed on the surface of the first substrate 110 may be transferred to the second substrate 210. The separating method in the present embodiment includes a separation starting point forming step and a separating step.

First, the separation starting point forming step will be described with reference to FIGS. 2-4. The separation starting point forming step is performed using the chuck table 3, the water supply unit 6, and the volume expansive unit 8 that form the separating apparatus 1. In the separation starting point forming step, the bonded substrate 300 is held by the chuck table 3 on the second wafer 200 side and conveyed by a conveyer, which is not shown. Meanwhile, the Y-axis moving unit 4 and the X-axis moving unit 5 are driven to move the chuck table 3 such that the outer peripheral edge of the bonded substrate 300 is located straight below the emitter head 82.

Subsequently, as shown in FIG. 2, the water L is supplied sideward from the water supply unit 6 toward the outer peripheral edge of the bonded substrate 300. Due to surface tension (capillary action), the water L supplied to the outer peripheral edge of the bonded substrate 300 reaches the vicinity of an interface between the first substrate 110 and the insulating film 135.

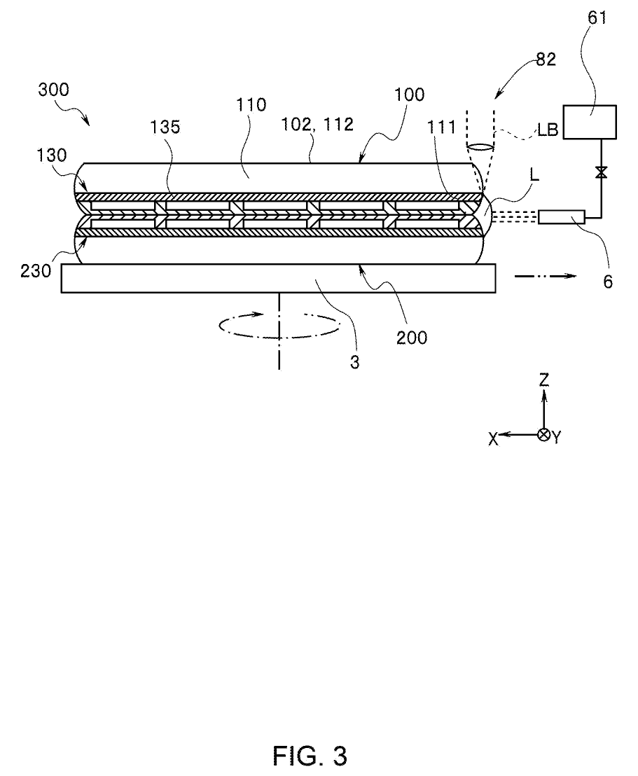

Further, as shown in FIG. 3, the laser beam LB having a transmissive wavelength is emitted from the emitter head 82 toward the bonded substrate 300 onto the first substrate 110 of the first wafer 100 from the back surface 102 of the first wafer 100. In other words, the laser beam LB emitted from the emitter head 82 irradiates the first wafer 100 from the first substrate 110 side (back surface 102 side).

The laser beam LB used in the separation starting point forming step is set to have a wavelength λ in a range between 2 μm and 20 μm, inclusive. By setting the wavelength λ within this range, the laser beam LB is enabled to pass through the first substrate 110 of the first wafer 100 and to be focused efficiently on the interface between the first substrate 110 and the insulating film 135. Moreover, by setting the wavelength λ within this range, energy of the laser beam LB may be efficiently absorbed by the water L reaching the interface between the first substrate 110 and the insulating film 135, which is a focusing position.

The laser beam LB emitted from the emitter head 82 is adjusted by the focal point position adjustment system (not shown) of the emitter head 82 so as to be focused on the interface between the first substrate 110 and the insulating film 135. After the adjustment, the laser beam LB is emitted in a manner to form, for example, a spiral path centered on a center of the first wafer 100. In particular, as shown in FIG. 3, the chuck table 3 holding the bonded substrate 300 is rotated around the axis extending in the Z-axis direction and is simultaneously moved in a direction indicated by a dash-and-dots arrow in FIG. 3, thereby relatively moving the chuck table 3 and the emitter head 82 in the X-axis direction.

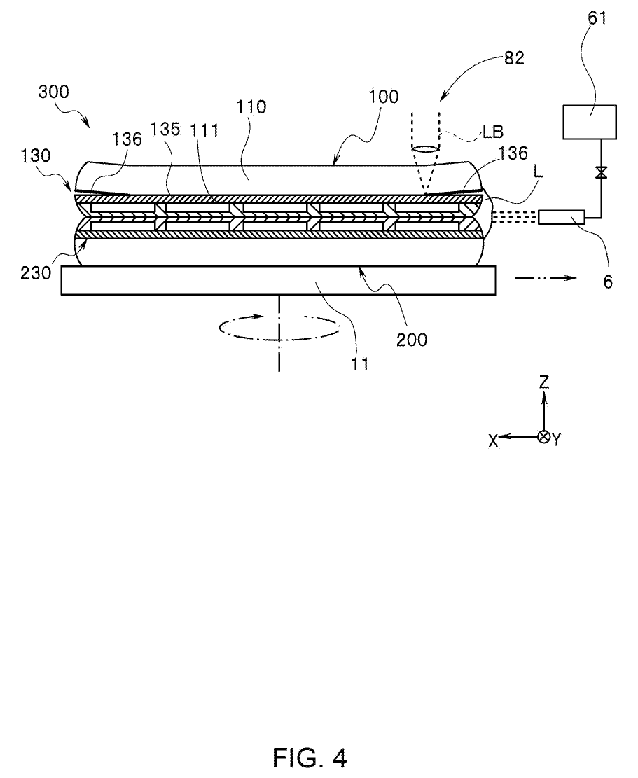

As shown in FIG. 4, by this relative movement, an irradiation position with the laser beam LB shifts from the outer peripheral edge, which is on one side in a planar direction of the first wafer 100, toward the center, which is on the other side in the planar direction. While the laser beam LB is emitted, the water L is continuously supplied from the water supply unit 6. Accordingly, due to surface tension (capillary action), the water L supplied to the outer peripheral edge of the bonded substrate 300 reaches the vicinity of the interface between the first substrate 110 and the insulating film 135.

The water L is heated and evaporated by energy of the laser beam LB, and a volume thereof expands. A lower surface (front surface 111) of the first substrate 110 is pressurized upward and an upper surface of the insulating film 135 is pressurized downward by an evaporation reaction force generated during the volume expansion. In other words, at the focal point position of the laser beam LB, the interface between the first substrate 110 and the insulating film 135 distorts due to the water L, of which volume has expanded by evaporation, and a region where the first substrate 110 separates easily (separation starting point 136) is formed.

As the irradiation position with the laser beam LB shifts from the outer peripheral edge, which is on the one side in the planar direction of the first wafer 100, toward the center, which is on the other side in the planar direction, the separation starting point 136 develops from the outer peripheral edge toward the center. As the separation starting point 136 develops, the water L supplied from the water supply unit 6 proceeds to an end of the separation starting point 136 (an end toward the center of the first wafer 100) by the capillary action. As such, the water L is supplied to the irradiation position with the laser beam LB continuously, and the separation starting point 136 is continuously formed.

After irradiating with the laser beam LB within a range from the outer peripheral edge to a predetermined position, emittance of the laser beam LB is stopped. Accordingly, a circular region from the center of the first wafer 100 to the predetermined position is left unirradiated with the laser beam LB, while the interface between the first substrate 110 and the insulating film 135 is irradiated with the laser beam LB in a ring-shaped (annular) region on the outside of the circular region.

In the region irradiated with the laser beam LB, the first substrate 110 is deformed as shown in FIG. 4 due to the volume expansion of the water L. In other words, in the ring-shaped region, the first substrate 110 separates from the insulating film 135 and stays in a lifted and warped state. In other words, the first substrate 110 deforms into a form such that a position of the first substrate 110 in a direction (Z-axis direction) intersecting the planar direction is different between the outer periphery, which is on the one side in the planar direction (horizontal direction) of the first substrate 110, and the center side, which is on the other side in the planar direction. As such, the interface between the first substrate 110 and the insulating film 135 distorts, and the separation starting point 136 is formed in the ring-shaped region.

Note that the range in which the separation starting point 136 is formed is not limited to the ring-shaped region described above. For example, the separation starting point 136 may be formed over the entire interface between the first substrate 110 and the insulating film 135. In this arrangement, the laser beam LB is emitted in a range from the outer peripheral edge to the center of the first wafer 100. The range in which the separation starting point 136 is formed may be set depending on, for example, a material or a formation method of the insulating film 135, or a bonding strength between the first substrate 110 and the insulating film 135. For example, when the insulating film 135 is a film formed in a solid-phase method, such as a silicon oxide film (SiO2 film) formed by thermal oxidation, a density of the insulating film 135 is high and the bonding strength with the first substrate 110 is high, and thus it may be preferable to form the separation starting point 136 over the entire interface between the first substrate 110 and the insulating film 135. For another example, when the insulating film 135 is a film generated in a gas-phase method, such as a silicon oxide film (SiO2 film) formed in a CVD method, the density of the insulating film 135 is low and the bonding strength with the first substrate 110 is low, and thus the separation starting point 136 may be formed in a ring shape.

Note that, when the first substrate 110 and the insulating film 135 are bonded by siloxane bonds (Si-O-Si), the siloxane bonds are broken by a reaction between the siloxane bonds and water molecules at the focal point position of the laser beam LB, and thus a bonding force between the first substrate 110 and the insulating film 135 is further weakened. Accordingly, the separation starting point 136 may be formed more easily.

After the separation starting point forming step, a separating step for separating the first substrate 110 and the second substrate 210 from each other is performed as shown in FIGS. 5-6. The separating step is performed using the chuck table 3 and the separating mechanism 9 that form the separating apparatus 1. In the separating step, the chuck table 3 holding the bonded substrate 300, in which the separation starting point 136 has been formed, is driven by the Y-axis moving unit 4 and the X-axis moving unit 5 and is moved to the position straight below the holding pad 92.

As shown in FIG. 5, a disc-shaped porous member 921 made of, for example, porous ceramic is incorporated into a lower central portion of the holding pad 92. The porous member 921 is in communication with a suction source 93 such as a vacuum pump. When the porous member 921 is evacuated by the suction source 93, a negative pressure is generated in the porous member 921, and the back surface 102 of the first wafer 100 in the bonded substrate 300 is held by suction to be drawn by the negative pressure.

Thereafter, as shown in FIG. 6, the holding pad 92 is lifted via the removing mechanism 91, and a force to pull the first substrate 110 apart from the second substrate 210 is applied. Accordingly, with the separation starting point 136 as a boundary, the lower surface (front surface 111) of the first substrate 110 is separated from the upper surface of the insulating film 135, and the first substrate 110 is separated from the bonded substrate 300. After separating the first substrate 110, the first devices 131 are maintained bonded to the second wafer 200. Thus, by performing the separating step, the first devices 131 are transferred (left) to the second wafer 200, and the bonded substrate 300 in which such transfer is completed is provided.

As described above, the separating apparatus 1 described above has the water supply unit 6 and the volume expansive unit 8. By the volume expansive unit 8 emitting the laser beam LB onto the interface between the first substrate 110 and the insulating film 135 and by the water supply unit 6 simultaneously supplying the water L from the side of the bonded substrate 300 toward the outer peripheral edge, the separation starting point 136 where the first substrate 110 is easily separated from the insulating film 135 may be formed. Therefore, when the first substrate 110 is separated from the bonded substrate 300 by the separating mechanism 9, chipping or cracking of the outer periphery of the wafer may be prevented. Further, the separation starting point 136 is formed by the volume expansion of the water L; therefore, generation of foreign matter (dust) may be prevented in the separation starting point forming step and the separating step.

The above described the separating method, in which two device layers are formed by stacking the first devices 131 on the second devices 231. Note that, according to this method, optionally, three or more similar device layers may be formed by repeating this method. Moreover, the above described the case where the first devices 131 formed on the first wafer 100 are transferred to the second wafer 200. However, optionally, the second devices 231 formed on the second wafer 200 may be transferred to the first wafer 100. In this arrangement, the separation starting point may be formed by emitting the laser beam LB onto an interface between the second substrate 210 and the insulating film 235.

While an embodiment of the present disclosure has been described, the above-described embodiment has been presented by way of example and is not intended to limit the scope of the disclosure. The embodiment of the present disclosure may be modified, substituted, or altered in various ways without departing from the spirit of the technical idea of the present disclosure. The above-described embodiment and modifications thereof are included in the scope and spirit of the disclosure, and are included in the scope of the disclosure described in the claims and their equivalents.

As described above, the separating apparatus of the present disclosure is a separating apparatus capable of separating one substrate from a bonded substrate formed by bonding one substrate on which devices are formed and another substrate. In particular, the separating apparatus may be useful for manufacturing a semiconductor device that connects laminated devices to each other using, for example, a Through Silicon Via (TSV).

What is claimed is:

1. A separating apparatus configured to separate a first substrate from a bonded substrate where a first wafer and a second substrate are bonded with a bonding member, the first wafer including the first substrate and devices formed on a surface of the first substrate, to transfer the devices to the second substrate, the separating apparatus comprising:
a water supply unit configured to supply water or water vapor to an outer peripheral edge of the bonded substrate;
a volume expansive unit configured to emit a laser beam having a wavelength absorptive in the water onto the water supplied by the water supply unit directly or through the first substrate or the second substrate for causing the water to expand in a volume thereof; and
a separating mechanism configured to hold at least one of the first substrate or the second substrate and separate the first substrate and the second substrate from each other.

2. A separating method for separating a first substrate from a bonded substrate where a first wafer and a second substrate are bonded with a bonding member, the first wafer including the first substrate and devices formed on a surface of the first substrate, and transferring the devices to the second substrate, the method comprising:
forming a separation starting point at least on an outer peripheral edge of the first wafer at a boundary between the devices and the first substrate by supplying water or water vapor to the outer peripheral edge of the first wafer and emitting a laser beam having a wavelength absorptive in the water onto the water and causing the water to expand in a volume thereof; and
holding at least one of the first substrate or the second substrate and separating the first substrate and the second substrate from each other.
